(19) United States
(12) Patent Application Publication
(10) Pub. No.: US 2009/0135031 A1
(43) Pub. Date: May 28, 2009

(54) Armored Capacitive Keypad

(75) Inventor: Thomas Lawrence Rockwell, Rochester, NY (US)

Correspondence Address: Key Systems, Inc.;c/o BROWN & MICHAELS, PC, 400 M&T BANK BLDG, 118 NORTH TIOGA STREET, ITHACA, NY, 14850, US

(73) Assignee: KEY SYSTEMS, INC., Fishers, NY (US)

(21) Appl. No.: 11/944,979

(22) Filed: Nov. 26, 2007

(51) Int. Cl. H03K 17/955

(52) U.S. Cl. 341/33

(57) ABSTRACT

An apparatus and method for detecting a key press using an armored capacitive keypad device. The device consists of two interdigitated electrodes, located behind a protective metal plate, and separated by an insulating gap or material. An electronic driver circuit sends a signal to one of the electrodes and senses the change in signal with the proximity of a finger to the key. The driver is calibrated with the metal plate in place such that the finger can be sensed through the metal plate. The device is tamper resistant and provides some immunity to external electromagnetic interference as well.

### FIELD OF THE INVENTION

This invention relates to capacitive keypad entry devices and more particularly relates to an armored keypad apparatus and method for data entry into a protected device.

### BACKGROUND OF THE INVENTION

Keypads and keyboards are familiar devices used to input numeric or alphanumeric data into computers and other electronic devices. The technology used for most common types of keys, such as a computer keyboard, is mechanical, where a spring-loaded key is depressed by a finger and electrical contact is made when the key is fully depressed. It is basically a variation of the momentary contact switch. A second technology is the flexible membrane keypad, commonly found on many microwave ovens. It uses a flexible insulator membrane bubble that has a conductive coating. When pressed, the conductor on the flexible bubble makes contact with the conductor on the substrate below, completing the circuit. A third technology uses a piezo-electric material, which, when pressed, generates a voltage that can be sensed by the underlying circuit board. A fourth technology, the one of interest here, is the capacitive keypad. When a finger is brought in close proximity to an electrode structure, a change in the electric field occurs, inducing a change in current flow which is sensed by electronics on an underlying or nearby circuit board. The capacitive keypad is known in the art and has the advantage of no moving parts. It doesn't suffer from contact resistance or corrosion, and can be placed behind a non-conductive dielectric to protect the electrodes from wear.

For high security purposes, there is a need to restrict access to buildings, offices, and laboratories or to lock boxes containing access keys or confidential information. The buildings might be limited access government facilities. The lock boxes might contain keys to automobiles on a car dealer's lot or cash and receipts from a bank or casino. Because the keypad may be located on the outside of a building and accessible to the general population, it needs to be mechanically protected to be tamper proof or tamper resistant, especially to deliberate attack from a chisel or an electric drill. Furthermore, it is also desirable to have it partially electrically shielded as well, to discourage electronic tampering and to isolate it, at least to some extent, from external electromagnetic interference (EMI).

There have been a number of solutions proposed for vandal proof or EMI shielded keypad applications. For example:

U.S. Pat. No. 7,002,084 (Cox, et al) discloses the use of a touch sensitive capacitive keypad located behind a rigid clear plastic panel and adhesively sealed to provide a watertight enclosure. The device is intended to be employed in the meat packing industry and is made to withstand being washed down with water under high pressure. It is not intended to be electrically shielded or drill proof;

U.S. Pat. No. 5,557,079 (Jackson et al.) discloses an electrically shielded keypad for a two way portable radio. It employs mechanical keys in the keypad, but is not intended to be vandal or tamper proof;

U.S. Pat. No. 5,513,078 (Komrska et al.) discloses an electrically shielded keypad for a radiotelephone that shields the internal electronics from electrical interference from the transmitting antenna. It employs bubble membrane switches in the keypad but is not intended to be tamperproof; and

U.S. Pat. No. 4,716,262 (Morse) discloses a vandal resistant telephone keypad switch, using mechanical keys.

The above references provide for electrical shielding or some type of vandal protection. Only one has a capacitive keyboard and it is neither electrically shielded nor very well protected because of its plastic cover. In the past, keypads with non-capacitive mechanical buttons have often been addressed with a pencil or sharp stylus object, damaging the keypad. It can be appreciated that there would be significant benefits to a keypad that had no moving parts and could be protected mechanically against intrusion from vandals or a determined attack and provide a measure of electrical shielding as well. Such a keypad could be mounted on the exterior of a building, and be sufficiently resistant to the weather and human tampering as not to require a surveillance camera, yet provide robust and reliable sensing of finger touch. Pencils or other sharp objects that can damage a keypad, not having the high dielectric constant of human tissue, would not work reliably, thus discouraging their use.

The present description is directed in particular to elements forming part of, or cooperating more directly with, apparatus in accordance with the invention. It is to be understood that elements not specifically shown or described may take various forms well known to those skilled in the art.

The Basic Capacitor

The present invention uses the capacitance of an insulating spacer, the air and the human body in the process of sensing a “key press”. In order to better understand the operation of the present invention, it is first useful to review the elements of a capacitor.

FIG. 1 shows a capacitor, consisting of two metal electrodes 11, 12 separated by an insulating material 18. the capacitance C is determined by:

C=keA/D

where k is the dielectric constant of the insulator between the plates, e is the permittivity of free space (the dielectric constant of air), A is the area of the electrode, and D is the separation distance between electrodes. In a capacitive keypad switch, bringing a finger near the key effectively introduces another electrode and reduces D, changing the capacitance. This action results in a net flow of charge which is sensed by the electronics. The value e represents the contribution of the air between the finger and the other two electrodes. The finger need not touch the surface to be sensed.

Capacitive Keypad

FIG. 2 shows a more typical structure 10 for a switch in a capacitive keypad. The two electrodes 11, 12 are side by side on an insulating protective panel 17, which can be almost any dielectric—typically glass or plastic, but it could be ceramic, or even wood. Electronic driver circuit 15, which can be, for example, a QT60168 or QT60248 driver IC manufactured by Quantum Research Group, Ltd., of the United Kingdom, sends a pulse train 16 (or a sine wave) into the electrode 11 and senses changes in electrical charge forced across an electrode by a pulse edge. The electric field lines 13 formed by the signal from the driver chip arc from one electrode X to a second electrode Y inside the insulator. There are also some fringing field lines 14 that may extend out of the insulator.

Bringing a finger in close proximity or touching the insulating panel 17, changes the electric field and therefore in the charge flow, as shown in FIG. 3. Because of the water content of the human body and resulting high dielectric constant, the finger becomes a third electrode, a virtual ground 19. The field lines are attracted to the finger, causing two currents to flow: I₁ between the two electrodes 11, 12, and I₂ from the electrodes to the finger. The driver circuit 15 senses this change in current or the equivalent change in AC impedance (depending upon the driver manufacturer), and records a key “press” by providing an appropriate “touched” signal on the circuit output 33. One need not actually touch the surface, but merely bring the finger in close proximity. In practice, most users touch the surface.

Methods other than that of Quantum of implementing detection of a finger are also in the literature. The Sensor magazine article “Playing the E-Field: Capacitance Sensors in Action”, P. Sieh and M. Steffen, September 2006 asserts that a sine wave is better than a square wave because signal interference is less of a problem. The authors, from Freescale Semiconductor Inc., also presume that the protective layer is a dielectric. They point out that larger electrodes have greater range and sensitivity, but are more susceptible to interference, electrical noise, and stray electric field paths.

Other general guidelines to keypad electrode design are noted in the Quantum Research Group Application note, 2004 where they recommend that the electrode area be as large as practical, but that the size of a fingertip forms a natural limit. The electrode can exceed the size of the fingertip by about 3 mm, because the electric fields drop off near the edges anyway.

### SUMMARY OF THE INVENTION

A robust and reliable keypad for data entry, resistant to vandalism and deliberate attack.

### BRIEF DESCRIPTION OF THE DRAWINGS

FIG. 1 is a diagrammatic view of a capacitor showing the plates and dielectric spacer;

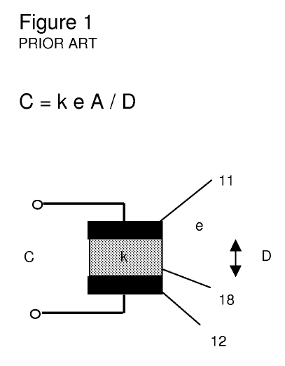

FIG. 2 is a schematic view of a capacitive keypad switch with an overlying insulating dielectric panel, showing the electric field lines;

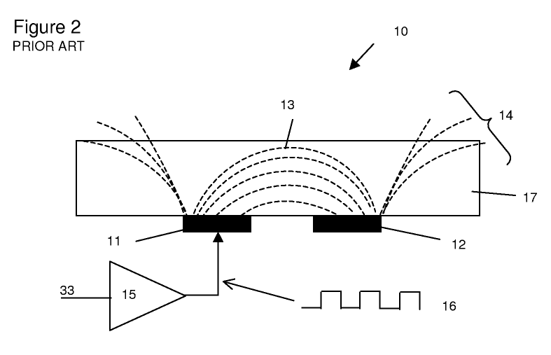

FIG. 3 is a schematic view of the same capacitive switch, showing how the electric field is altered by a finger;

FIG. 4 is a similar schematic view with a thin overlying insulator and a metal plate, showing how some of the electric field lines still penetrate to the finger;

FIG. 5 is a schematic view of a basic armored capacitive keypad switch;

FIG. 6 is a plan view of keypad electrode pattern, upper surface;

FIG. 7 is a plan view of the electrode interconnections, lower level;

FIG. 8 is a plan view of the combined upper and lower patterns.

### DETAILED DESCRIPTION OF THE INVENTION

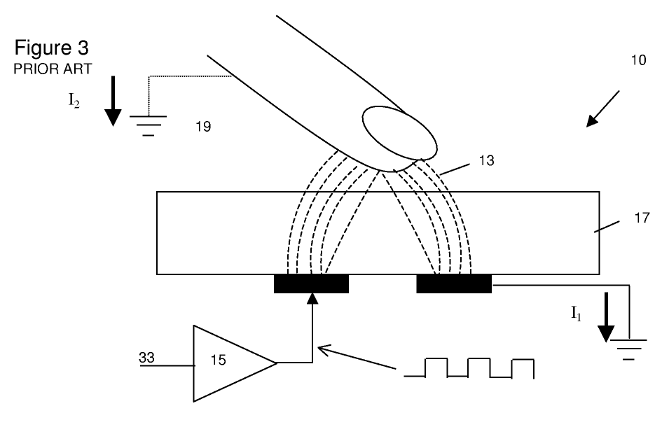

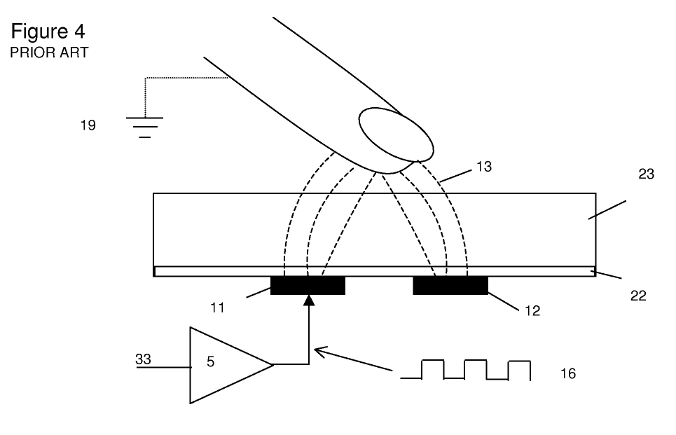

Conventional wisdom says that replacing the protective dielectric insulating panel 17 of FIG. 3 with a metal plate 23 (FIG. 4) won't work, even if it is not touching electrodes 11, 12, because the electric field lines will not penetrate the metal plate 23. That line of thinking is not entirely true.

As shown in FIG. 4, while the electric field caused by the signal 16 from the driver circuit 15 is substantially attenuated by the metal plate (fewer field lines) the e-field lines are still attracted to the finger, causing a change in the flow which is detected by the driver circuit 15, which reacts by providing a “touch detected” signal on output 33. The caveat here is that the metal plate has to be electrically isolated or “floating”. Grounding the plate will essentially prevent the finger from having an effect on the sensed signal.

The electronic driver circuit 15 allows for recalibration due to drift in material properties over time. To detect the altered signal when using a metal plate, the driver electronics needs to be calibrated, per the manufacturer's instructions, but with the metal plate in place to provide a robust detection signal. This calibration allows for the effect of the metal plate on the detected signal.

The metal plate 23 will also provide some attenuation of external electromagnetic fields, since these fields will produce eddy currents in the metal and dissipate some of the energy. The metal plate would typically be prevented from shorting the electrodes 11, 12 by using an insulating layer 22 such as a thin insulating spacer or air gap. The metal plate could be made of any common metal such as stainless steel or aluminum, but hardened tool steel gives excellent protection against tools such as drills, saws and chisels. Those skilled in the art may propose similar materials other than specifically mentioned here, but these are considered within the scope of this invention.

Structure of Armored Keypad

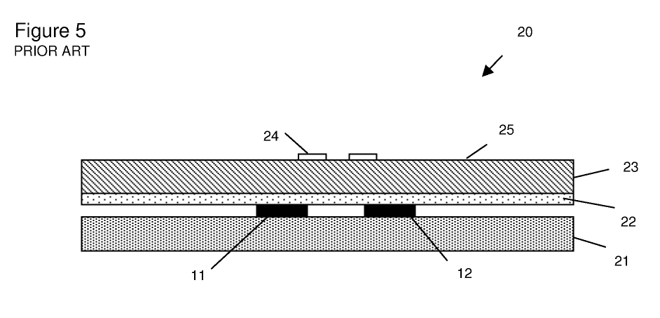

FIG. 5 shows the basic structure of an armored capacitive keypad device 20. The substrate 21 would typically be a printed circuit board material such as fiberglass-epoxy. The electrode patterns 11, 12 (the X and Y electrodes shown previously) and some interconnects (not shown) would be placed on the upper surface of the board and the remaining interconnects with vias (not shown) on the lower surface of the board. An insulating layer 22 is placed between the electrodes 11, 12 and the metal protective plate 23 to prevent shorting of the electrodes. This insulation layer can be a thin insulating spacer, as shown in FIG. 5, or an air gap.

On the touch surface 25 of the metal plate, a label or numerical key identifier 24 can be placed. Typically, this label can be painted, embossed, engraved, anodized or silk-screened. Any suitable process that provides good wear resistance is acceptable.

In a case where electrical shielding is unnecessary and shatter resistance is adequate, the metal could be replaced with a durable ceramic such as zirconia, beryllia, or alumina, or any combination of those. The device would look like that shown in FIG. 5, where the protective metal plate 23 is replaced by a ceramic plate. The driver needs to be calibrated with the ceramic plate in place.

Electrode Patterns

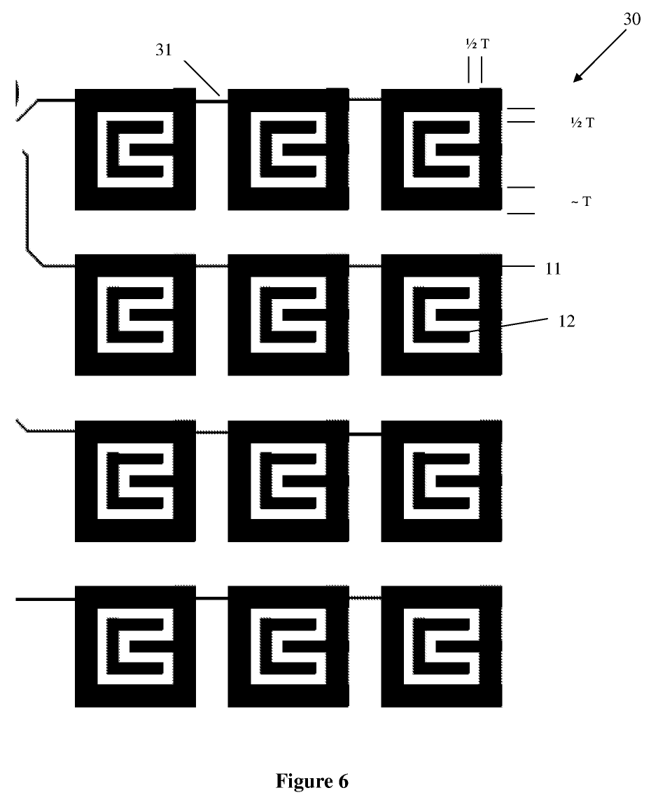

FIG. 6 shows a suitable electrode pattern 30 for the keypad electrodes, typically placed on the top surface of the substrate 21, such that a finger can be reliably detected through a metal plate. Electrode interconnects 31 connect the X electrodes 11 on the top surface of substrate 21.

The pattern shown in the example uses an interdigitated electrode structure, a simplified version of that shown in the Quantum Application Note, to provide numerous electric field lines to reliably sense a finger coming from any direction. According to the application note, the patterns for the keys can be any shape, including round, square, rectangular, etc. The electrode width and the electrode gap together form a dimension T. T should be similar to the thickness of the plastic touch panel. Smaller dimensions will work, but they will reduce signal strength.

In the case of the metal protective plate of this invention, the thinner the plate, the better the field penetration to the finger and the better the sense signal. The metal plate thickness is somewhat of a tradeoff between robust sensing and tamper resistance but there are a range of thicknesses that will work well. Tool steel at least as thick as 2 mm is acceptable.

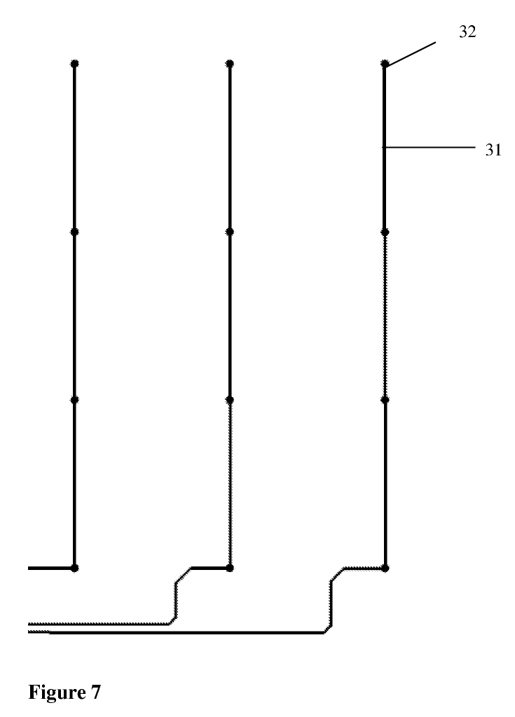

FIG. 7 shows the electrode interconnects 31 and vias 32 for the Y electrode 12 traces, typically located on the bottom surface of the substrate. It is appreciated that those skilled in the art could employ an electrode pattern allowing all traces to be located on one surface, or to place the electrodes on the insulating spacer 22 instead and eliminate the circuit board substrate 21.

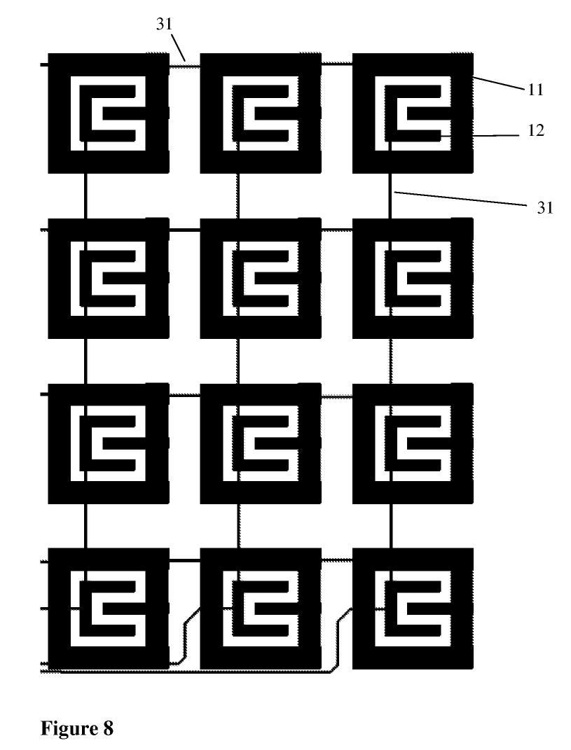

FIG. 8 shows the combination of the electrodes and traces on the upper and lower level, combined into a single view.

The invention has been described in detail but it will be understood that variations and modifications can be affected within the scope of the invention.

### REFERENCE NUMBER LIST

10 Capacitive keypad structure
11 X electrode
12 Y electrode
13 Inter-electrode field lines
14 Fringing field lines
15 Electronic driver circuit
16 Pulse train from driver circuit 15
17 Insulating (dielectric) protective panel
18 Insulating gap or layer
19 Virtual ground through finger
20 Armored capacitive keypad device
21 Substrate (printed circuit board)
22 Insulating (dielectric) spacer
23 Protective metal plate
24 Label for individual key
25 Touch surface
30 Electrode pattern
31 Electrode interconnect
32 Via
33 Output of driver circuit 15

What is claimed is:

1. An armored capacitive keypad comprising an array of switches, each switch comprising:
a dielectric substrate having an upper surface and a lower surface;
at least one pair of electrodes upon the upper surface of the substrate;
an electrically isolated protective metal plate forming a surface for the keypad, having a lower surface facing the at least one pair of electrodes, and a touch surface opposite the lower surface; and
an insulating layer between the electrodes and the lower surface of the protective metal plate;
a driver circuit coupled to one of the electrodes of the at least one pair of electrodes, the driver circuit providing a drive signal to the electrode such that an electric field is created between the electrode and an other electrode of the pair of electrodes, and having an output with a touch signal responsive to changes in the electric field,
such that when an object approaches the touch surface of the plate adjacent to the at least one pair of electrodes, the driver circuit causes the touch signal to change.

2. The keypad of claim 1, in which the metal plate is formed of a metal selected from a group consisting of tool steel, aluminum, and stainless steel.

3. The keypad of claim 1, further comprising key indicia applied to the touch surface of the metal plate, opposite the at least one pair of electrodes.

4. The keypad of claim 1, in which there are a plurality of pairs of electrodes, and the driver circuit is separately coupled to one electrode of each of the pairs of electrodes.

5. The keypad of claim 4, in which the output of the driver circuit provides a separate touch signal for each of the plurality of pairs of electrodes.

6. The keypad of claim 1, in which the at least one pair of electrodes is formed in an interdigitated electrode structure.

7. The keypad of claim 1, in which the driver circuit is coupled to the electrode through traces formed on a surface of the substrate.

8. The keypad of claim 1, in which the insulating layer is a dielectric material

9. The keypad of claim 1, in which the insulating layer is an air gap.

10. An armored capacitive switch comprising:
a dielectric substrate having an upper surface and a lower surface;
at least one pair of electrodes upon the upper surface of the substrate;
an electrically isolated protective metal plate forming a surface for the switch, having a lower surface facing the at least one pair of electrodes, and a touch surface opposite the lower surface; and
an insulating layer between the electrodes and the lower surface of the protective metal plate;
a driver circuit coupled to one of the electrodes of the at least one pair of electrodes, the driver circuit providing a drive signal to the electrode such that an electric field is created between the electrode and an other electrode of the pair of electrodes, and having an output with a touch signal responsive to changes in the electric field,
such that when an object approaches the touch surface of the plate adjacent to the at least one pair of electrodes, the driver circuit causes the touch signal to change.

11. The switch of claim 10, in which the metal plate is formed of a metal selected from a group consisting of tool steel, aluminum, and stainless steel.

12. The switch of claim 10, further comprising key indicia applied to the touch surface of the metal plate, opposite the at least one pair of electrodes.

13. The switch of claim 10, in which the driver circuit is coupled to the electrode through traces formed on a surface of the substrate.

14. The switch of claim 10, in which the insulating layer is a dielectric material

15. The switch of claim 10, in which the insulating layer is an air gap.
